(19) United States
(12) Patent Application Publication
(10) Pub. No.: US 2011/0304010 A1
(43) Pub. Date: Dec. 15, 2011

(54) ELECTROSTATIC DISCHARGE PROTECTION SCHEME FOR SEMICONDUCTOR DEVICE STACKING PROCESS

(75) Inventors: Zhe-Wei Jiang, Yilan County (TW); Ding-Ming Kwai, Hsinchu County (TW); Shih-Hung Chen, Taipei County (TW)

(73) Assignee: INDUSTRIAL TECHNOLOGY RESEARCH INSTITUTE, Hsinchu (TW)

(21) Appl. No.: 12/851,539

(22) Filed: Aug. 5, 2010

(30) Foreign Application Priority Data
Jun. 11, 2010 (TW) 99119089

(51) Int. Cl. H01L 23/60

(52) U.S. Cl. 257/528; 361/56; 257/774; 257/E23.011; 257/777; 257/E23.169

(57) ABSTRACT

An electrostatic discharge (ESD) protection scheme for a semiconductor device stacking process is provided, in which an equivalent electrical resistance of a specific path is designed to be less than an equivalent electrical resistance of other paths. Accordingly, when a first active layer and a second active layer in the semiconductor device are stacked, by designing suitable ESD protection cells on such a specific path, electrical charges accumulated on the top layer wafer (or die) select such a specific path over the other paths to be released to the grounded bottom layer wafer (or die), so as to achieve an ESD protection effect. In addition, since such a specific path also serves as a heat dissipation path in a three dimensional integrated circuit (3D IC), an overall heat resistance of the 3D IC may be reduced to improve a heat dissipation effect.

### CROSS-REFERENCE TO RELATED APPLICATION

This application claims the priority benefit of Taiwan application serial no. 99119089, filed on Jun. 11, 2010. The entirety of the above-mentioned patent application is hereby incorporated by reference herein and made a part of this specification.

### 1. TECHNICAL FIELD

The disclosure is related to a semiconductor device, and in particular to, an electrostatic discharge (ESD) protection scheme for a wafer and/or die stacking process.

### 2. BACKGROUND

Three dimensional integrated circuit (3D IC) stacking processes are mainly classified into die-to-wafer, wafer-to-wafer, and die-to-die stacking processes. Generally, when a robot manipulator sucks (or clenches) a top layer wafer (or die) and stacks it above a bottom layer wafer (or die), electrical charges (which are static electricity) are possibly generated on the top layer wafer (or die) due to friction or other factors when the robot manipulator is moving.

Hence during the process of stacking the top and bottom layer wafers (or dies), the electrical charges accumulated on the top layer wafer (or die) are discharged to the grounded bottom layer wafer (or die) through at least a pad of the top layer wafer (or die) and a corresponding bump of the bottom layer wafer (or die). Therefore, ESD current generated by such electrical charges is very likely to damage internal circuits that are located on the top or bottom layer wafer (or die) and electrically connected by through silicon vias (TSV).

On the other hand, since in 3D ICs, different wafers (or dies) are stacked, a result is that the heat resistance of the overall 3D IC structure is increased. Consequently, when a 3D IC is operated, a great amount of heat is generated, thereby increasing the overall operating temperature and decreasing reliability of the 3D IC.

Evidently, an important issue in the development of 3D IC technology is how to effectively release the accumulated charges (i.e., static electricity) when stacking different wafers (or dies) and how to dissipate heat after the wafers (or dies) are stacked.

### SUMMARY

In light of the above, the disclosure provides a semiconductor device which includes a first active layer that includes a first substrate; a plurality of first TSVs, wherein each of the first TSVs passes through the first substrate; and a first ESD protection cell that has at least a first doping area, so that the first ESD protection cell is embedded in the first substrate and is adjacent and electrically connected to a first specific TSV of the first TSVs.

It should be known that the general description above and the embodiments below are only exemplary and for descriptive purposes, and do not limit the scope of the claims.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a semiconductor device 100 according to an embodiment.

FIG. 2A is a schematic diagram of an ESD protection cell ESD_P1 in a box A in FIG. 1 according to an embodiment.

FIG. 2B is a schematic diagram of the ESD protection cell ESD_P1 in the box A in FIG. 1 according to another embodiment.

FIG. 2C is a schematic diagram of an ESD protection cell ESD_P2 in a box B in FIG. 1 according to an embodiment.

FIG. 2D is a schematic diagram of the ESD protection cell ESD_P2 in the box B in FIG. 1 according to another embodiment.

FIG. 3 shows a schematic illustrative diagram related to ESD protection according to an embodiment.

FIG. 4A is a schematic diagram in which a structure of a TSV T1′ on a path Path-1 is altered according to an embodiment.

FIG. 4B is a schematic diagram in which the structure of the TSV T1′ on the path Path-1 is altered according to another embodiment.

FIG. 4C is a schematic diagram in which the structure of the TSV T1′ on the path Path-1 is altered according to still another embodiment.

FIG. 5A is a schematic diagram in which a structure of a bump BP′ on the path Path-1 is altered according to an embodiment.

FIG. 5B is a schematic diagram in which the structure of the bump BP′ on the path Path-1 is altered according to another embodiment.

FIG. 5C is a schematic diagram in which the structure of the bump BP′ on the path Path-1 is altered according to still another embodiment.

FIG. 6 is a schematic diagram of a semiconductor device 100′ according to another embodiment.

FIG. 7A is a schematic diagram of an ESD protection cell ESD_P2′ in a box B′ in FIG. 6 according to an embodiment.

FIG. 7B is a schematic diagram of the ESD protection cell ESD_P2′ in the box B′ in FIG. 6 according to another embodiment.

FIG. 8 shows a schematic illustrative diagram related to ESD protection according to another embodiment.

### DETAILED DESCRIPTION OF DISCLOSED EMBODIMENTS

The following refers to the exemplary embodiments in detail and illustrates implementations of the exemplary embodiments in the accompanying drawings. In addition, whenever possible, the same reference numerals in the figures and embodiments represent the same or similar elements.

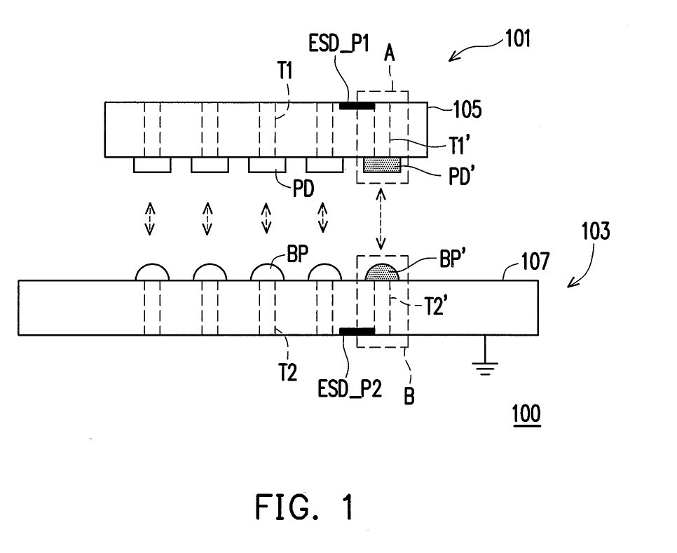

FIG. 1 is a schematic diagram of a semiconductor device 100 according to an embodiment. Referring to FIG. 1, the semiconductor device 100 includes a first active layer 101 and a second active layer 103. The first active layer 101 and the second active layer 103 may each be a wafer and/or a die (meaning that the first active layer 101 and the second active layer 103 may both be wafers or dies, or one of the first active layer 101 and the second active layer 103 may be a wafer and the other one of first active layer 101 and the second active layer 103 may be a die, or vice versa). The first active layer 101 includes a substrate 105, a plurality of TSVs T1, a plurality of pads PD, and at least one ESD protection cell ESD_P1; and the second active layer 103 includes a substrate 107, a plurality of TSVs T2, a plurality of bumps BP, and at least one ESD protection cell ESD_P2.

According to the present embodiment, each of the TSVs T1 passes through the substrate 105, and each of the TSVs T2 also passes through the substrate 107. In addition, the ESD protection cell ESD_P1 includes at least one first doping area (described in detail in the following), so that the ESD protection cell ESD_P1 is embedded in the substrate 105 and is adjacent and electrically connected to a first specific TSV T1′ of (among) the TSVs T1. Similarly, the ESD protection cell ESD_P2 includes at least one second doping area (described in detail in the following), so that the ESD protection cell ESD_P2 is embedded in the substrate 107 and is adjacent and electrically connected to a second specific TSV T2′ of (among) the TSVs T2. Hence the first specific TSV T1′ corresponds to the second specific TSV T2′.

On the other hand, each of the pads PD is located (disposed) outside the substrate 105 and is electrically connected to the corresponding TSV T1. Similarly, each of the bumps BP is located (disposed) outside the substrate 107 and is electrically connected to the corresponding TSV T2. It should be noted that each of the pads PD corresponds to each of the bumps BP, i.e. a one-to-one relationship. Therefore, the first active layer 101 and the second active layer 103 are stacked through the pads PD and the bumps BP, so that the semiconductor device 100 becomes a 3D IC.

The following describes in detail specific implementations of the ESD protection cells ESD_P1 and ESD_P2 according to the present embodiment.

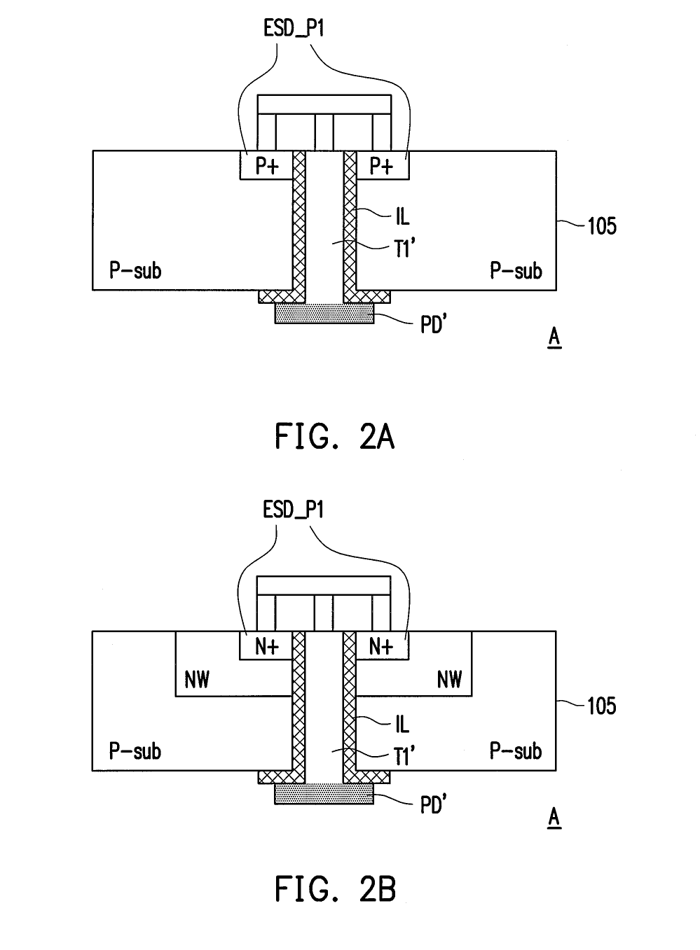

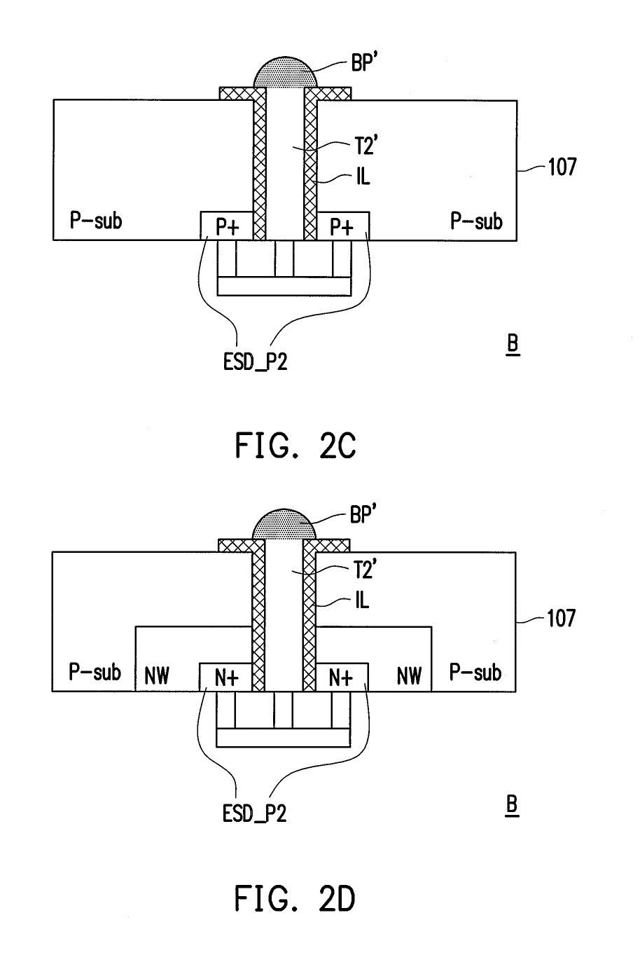

FIG. 2A is a schematic diagram of the ESD protection cell ESD_P1 in a box A in FIG. 1 according to an embodiment. Please refer to both FIGS. 1 and 2A. According to the present embodiment, if the substrate 105 is a P-type substrate (P-sub), the at least one first doping area of the ESD protection cell ESD_P1 is a P+ doping area (two P+ doping areas are exemplarily shown in FIG. 2A).

Moreover, FIG. 2B is a schematic diagram of the ESD protection cell ESD_P1 in the box A in FIG. 1 according to another embodiment. Please refer to both FIGS. 1 and 2B. According to the present embodiment, if the substrate 105 is the P-type substrate (P-sub), and if the first active layer 101 further includes a well that is embedded between the substrate 105 and the ESD protection cell ESD_P1, the well that is embedded between the substrate 105 and the ESD protection cell ESD_P1 is an N-well NW, and the at least one first doping area of the ESD protection cell ESD_P1 is an N+ doping area (two N+ doping areas are exemplarily shown in FIG. 2B). According to the present embodiment, the first specific TSV T1′ and the ESD protection cell ESD_P1 in the substrate 105 are adjacent and connected by metal line to each other, but insulated from each other (due to the presence of an insulation layer IL), and a pad PD′ which corresponds to the first specific TSV T1′ and the substrate 105 are also insulated from each other (also due to the presence of the insulation layer IL).

On the other hand, FIG. 2C is a schematic diagram of the ESD protection cell ESD_P2 in a box B in FIG. 1 according to an embodiment. Please refer to both FIGS. 1 and 2C. According to the present embodiment, if the substrate 107 is a P-type substrate (P-sub), the at least one second doping area of the ESD protection cell ESD_P2 is a P+ doping area (two P+ doping areas are exemplarily shown in FIG. 2C).

Moreover, FIG. 2D is a schematic diagram of the ESD protection cell ESD_P2 in the box B in FIG. 1 according to another embodiment. Please refer to both FIGS. 1 and 2D. According to the present embodiment, if the substrate 107 is the P-type substrate (P-sub), and if the second active layer 103 further includes a well that is embedded between the substrate 107 and the ESD protection cell ESD_P2, the well that is embedded between the substrate 107 and the ESD protection cell ESD_P2 is an N-well NW, and the at least one first doping area of the ESD protection cell ESD_P2 is an N+ doping area (two N+ doping areas are exemplarily shown in FIG. 2D). According to the present embodiment, the second specific TSV T2′ and the ESD protection cell ESD_P2 in the substrate 107 are adjacent and connected by metal line to each other, but insulated from each other (due to the presence of the insulation layer IL), and a bump BP′ which corresponds to the second specific TSV T2′ and the substrate 107 are also insulated from each other (also due to the presence of the insulation layer IL).

Hence according to the background disclosure, during the process of stacking the top and bottom layer wafers (or dies), the electrical charges accumulated on the top layer wafer (or die) are discharged to the grounded bottom layer wafer (or die) through the contact between at least a pad of the top layer wafer (or die) and a corresponding bump of the bottom layer wafer (or die). Accordingly, ESD current generated by such electrical charges is very likely to damage internal circuits that are located on the top or bottom layer wafer (or die) and electrically connected by the TSVs.

On the other hand, since in 3D ICs, different wafers (or dies) are stacked, a result is that the heat resistance of the overall 3D IC structure is increased. Consequently, when a 3D IC is operated, a great amount of heat is generated, thereby increasing the overall operating temperature and decreasing the reliability of the 3D IC.

In light of the above, in order to effectively release the electrical charges (which are static electricity) accumulated on the top layer wafer (or die) when stacking different wafers (or dies) and to dissipate heat after the stacking process, the present embodiment provides a “specific path” (which is described in detail in the following), so as to effectively release the electrical charges accumulated on the top layer wafer (or die) and to provide a heat dissipation path after the stacking process.

To be more specific, according to the above embodiments, since the ESD protection cells ESD_P1 and ESD_P2 which are respectively adjacent to the first and second specific TSVs T1′ and T2′ have the P+ doping areas (FIGS. 2A and 2C) or the N+ doping areas (FIGS. 2B and 2D), respectively. When each of the ESD protection cells ESD_P1 and ESD_P2 of the first and second specific TSVs T1′ and T2′ has the P+ doping area, the electrical charges (which are static electricity) accumulated on the substrate 105 (P-sub) (which is the top layer wafer (or die)) are guided to the grounded substrate 107 (P-sub) (which is the bottom layer wafer (or die)) through the specific path provided by the present embodiment, thereby realizing the goal of ESD protection.

Similarly, when each of the ESD protection cells ESD_P1 and ESD_P2 of the first and second specific TSVs T1′ and T2′ has the N+ doping area, the electrical charges (which are static electricity) accumulated in the N-well NW in the substrate 105 (P-sub) (which is the top layer wafer (or die)) are guided to the grounded substrate 107 (P-sub) (which is the bottom layer wafer (or die)) through the specific path provided by the present embodiment, thereby realizing the goal of ESD protection.

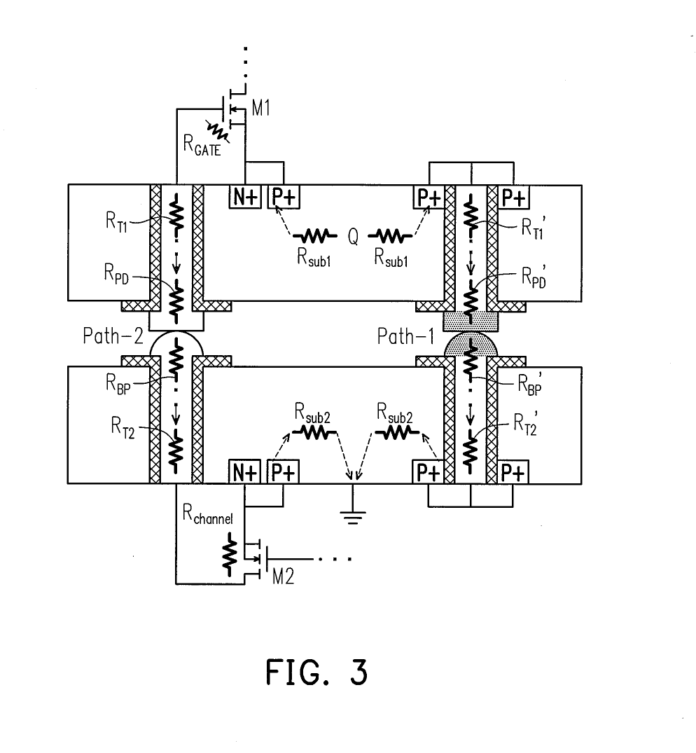

For example, FIG. 3 shows a schematic illustrative diagram related to ESD protection according to an embodiment. Please refer to FIG. 3, in which each of the ESD protection cells ESD_P1 and ESD_P2 has a P+ doping area. An example in which each of the ESD protection cells ESD_P1 and ESD_P2 has an N+ doping area may be deduced accordingly and is not described. A path Path-1 shown in FIG. 3 is the “specific path” which achieves the goal of ESD protection by utilizing the ESD protection cells ESD_P1 and ESD_P2, and a path Path-2 is a general “conventional path” of internal circuits which are electrically connected by TSVs T1 and T2.

According to FIG. 3, an equivalent electrical resistance R_{Path-1} for electrical charges Q accumulated on the substrate 105 (P-sub) (which is the top layer wafer (or die)) through the path Path-1 to ground is represented by the following equation 1:

R_{Path-1}=R_{sub1}+R_{T1′}+R_{PD′}+R_{PD′}+R_{BP′}+R_{T2′}+R_{T2′}+R_{sub2} 1

R_{sub1} is an equivalent electrical resistance of the substrate 105 (P-sub); R_{T1′} is an equivalent electrical resistance of the first specific TSV T1′; R_{PD′} is an equivalent electrical resistance of the pad PD′ (which is the pad corresponding to the specific path) corresponding to the first specific TSV T1′; R_{BP′} is an equivalent electrical resistance of the bump BP′ (which is the bump corresponding to the specific path) corresponding to the second specific TSV T2′; R_{T2′} is an equivalent electrical resistance of the second specific TSV T2′; and R_{sub2} is an equivalent electrical resistance of the substrate 107 (P-sub).

On the other hand, an equivalent electrical resistance R_{Path-2} for electrical charges Q accumulated on the substrate 105 (P-sub) (which is the top layer wafer (or die)) through the path Path-2 to ground is represented by the following equation 2:

R_{Path-2}=R_{sub1}+R_{GATE}+R_{T1}+R_{PD}+R_{BP}+R_{T2}+R_{channel}+R_{sub2} 2

R_{sub1} is the equivalent electrical resistance of the substrate 105 (P-sub); R_{GATE} is an equivalent electrical resistance of a gate of an NMOS transistor M1; R_{T1} is an equivalent electrical resistance of the TSV T1; R_{PD} is an equivalent electrical resistance of the pad PD (which is the pad corresponding to the conventional path) corresponding to the TSV T1; R_{BP} is an equivalent electrical resistance of the bump BP (which is the bump corresponding to the conventional path) corresponding to the TSV T2; R_{channel} is an equivalent electrical resistance of a channel of an NMOS transistor M2 when it is non-conducting; and R_{sub2} is the equivalent electrical resistance of the substrate 107 (P-sub).

It is assumed that the TSVs T1 and T1′ have the same structure, the TSVs T2 and T2′ have the same structure, the bumps BP and BP′ have the same structure, and the pads PD and PD′ have the same structure. Under such circumstances, the equivalent electrical resistance R_{T1} and the equivalent electrical resistance R_{T1′} of the TSVs T1 and T1′ are equal (i.e. R_{T1}=R_{T1′}), the equivalent electrical resistance R_{T2} and the equivalent electrical resistance R_{T2′} of the TSVs T2 and T2′ are equal (i.e. R_{T2}=R_{T2′}), the equivalent electrical resistance R_{BP} and the equivalent electrical resistance R_{BP′} of the bumps BP and BP′ are equal (i.e. R_{BP}=R_{BP′}), and the equivalent electrical resistance R_{PD} and the equivalent electrical resistance R_{PD′} of the bumps PD and PD′ are equal (i.e. R_{PD}=R_{PD′}). Hence a difference value between the equivalent electrical resistance R_{Path-1} and the equivalent electrical resistance R_{Path-2} of the paths Path-1 and Path-2 to ground is represented by the following equation 3:

R_{Path-2}−R_{Path-1}=R_{GATE}+R_{channel} 3

Therefore, compared with the path Path-1, the path Path-2 has the equivalent electrical resistance R_{Path-2} which further includes the equivalent electrical resistance R_{GATE} of the gate of the NMOS transistor M1 and the equivalent electrical resistance R_{channel} of the channel of the NMOS transistor M2 when it is non-conducting. The path Path-1 is hence a path which has a smaller equivalent electrical resistance relative to the path Path-2, so that the electrical charges Q (which are static electricity) accumulated on the substrate 105 (P-sub) (which is the top layer wafer (or die)) select the path Path-1 over the path Path-2 to be released to the grounded substrate 107 (P-sub) (which is the bottom layer wafer (or die)).

On the other hand, according to FIG. 3, after the top and bottom layer wafers (or dies) are stacked, heat dissipation paths of the 3D IC are provided by both of the paths Path-1 and Path-2. If the equivalent heat resistance of the path Path-1 and the equivalent heat resistance of the path Path-2 are respectively represented by R_{T-Path-1} and R_{T-Path-2}, an overall heat resistance of the 3D IC is the parallel value of the equivalent heat resistance R_{T-Path-1} and the equivalent heat resistance R_{T-Path-2} of the paths Path-1 and Path-2 (i.e. (R_{T-Path-1})(R_{T-Path-2})/R_{T-Path-1}+R_{T-Path-2}), and the parallel value is less than the value of the equivalent heat resistance R_{T-Path-2} of the path Path-2. Consequently, by including the specific path defined by the path Path-1, the overall heat resistance of the 3D IC is lowered, thereby enhancing heat dissipating effects and enhancing the overall reliability of the 3D IC.

Additionally, to make the electrical charges Q (which are static electricity) accumulated on the substrate 105 (P-sub) choose the path Path-1 over the path Path-2 to be released to the grounded substrate 107 (P-sub) (which is the bottom layer wafer (or die)), the present embodiment may also be implemented by altering the structures of the TSV T1′ and the bump BP′ on the path Path-1.

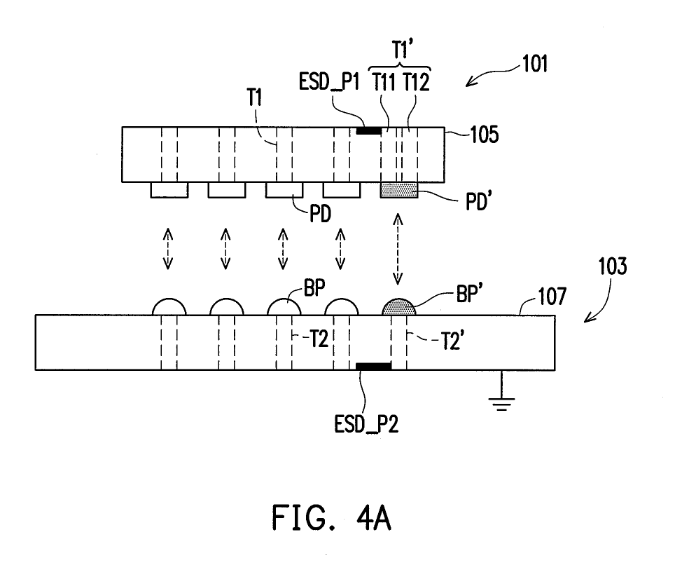

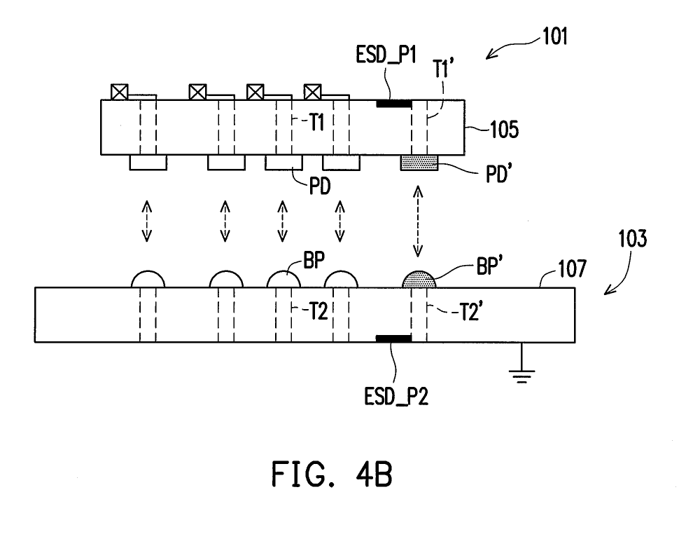

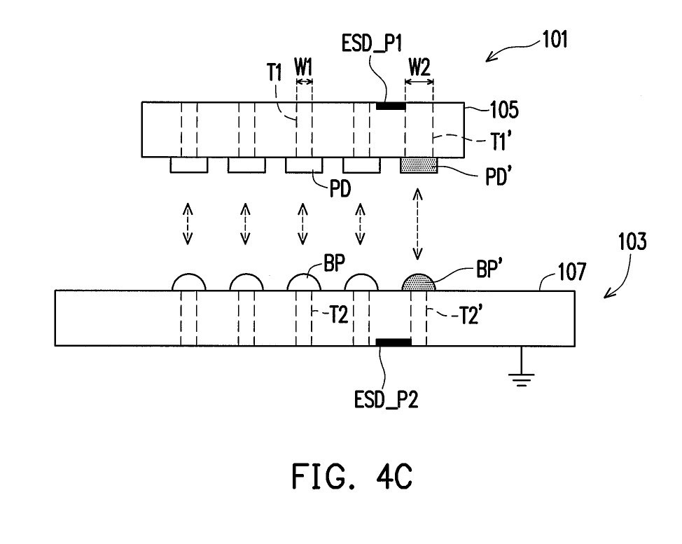

In further detail, FIG. 4A is a schematic diagram in which the structure of the TSV T1′ on the path Path-1 is altered according to an embodiment. Please refer to FIG. 4A. Compared with FIG. 1, the first specific TSV T1′ according to the present embodiment has at least two sub-TSVs T11 and T12 which are the same as the other TSVs T1 and connected in parallel. Therefore, the equivalent electrical resistance R_{T1′} of the TSV T1′ is less than the equivalent electrical resistance R_{T1} of the other TSVs T1.

In addition, FIG. 4B is a schematic diagram in which the structure of the TSV T1′ on the path Path-1 is altered according to another embodiment. Please refer to FIG. 4B. Compared with FIG. 1, by altering a routing length of a top metal of the first active layer 101 electrically connected to the TSV T1 according to the present embodiment, the routing length through which a signal is transmitted to the first specific TSV T1′ is shorter than the routing length through which the signal is transmitted to the other TSVs T1. The equivalent electrical resistance R_{T1′} of the TSV T1′ is hence less than the equivalent electrical resistance R_{T1} of the other TSVs T1.

In addition, FIG. 4C is a schematic diagram in which the structure of the TSV T1′ on the path Path-1 is altered according to still another embodiment. Please refer to FIG. 4C. Compared with FIG. 1, a width W2 of the first specific TSV T1′ is greater than a width W1 of the other TSVs T1. The equivalent electrical resistance R_{T1′} of the TSV T1′ is hence less than the equivalent electrical resistance R_{T1} of the other TSVs T1. Moreover, according to other embodiments, by altering the electrical conductivity of the first specific TSV T1′, the electrical conductivity of the first specific TSV T1′ is greater than the electrical conductivity of the other TSVs T1. The equivalent electrical resistance R_{T1′} of the TSV T1′ is hence less than the equivalent electrical resistance R_{T1} of the other TSVs T1.

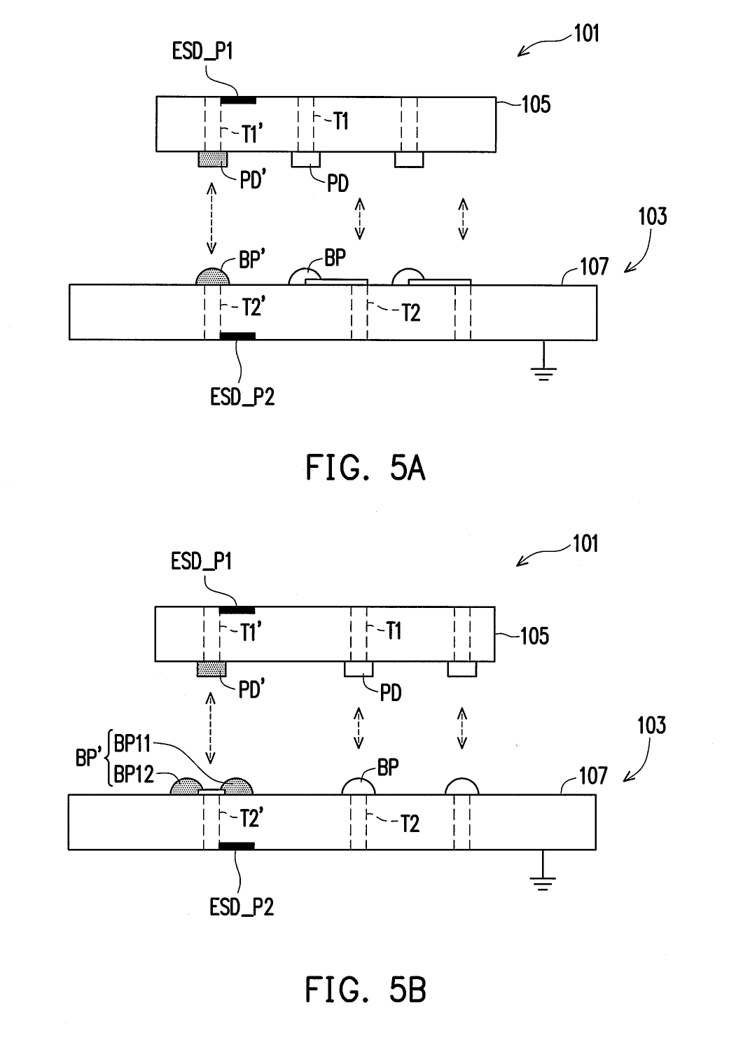

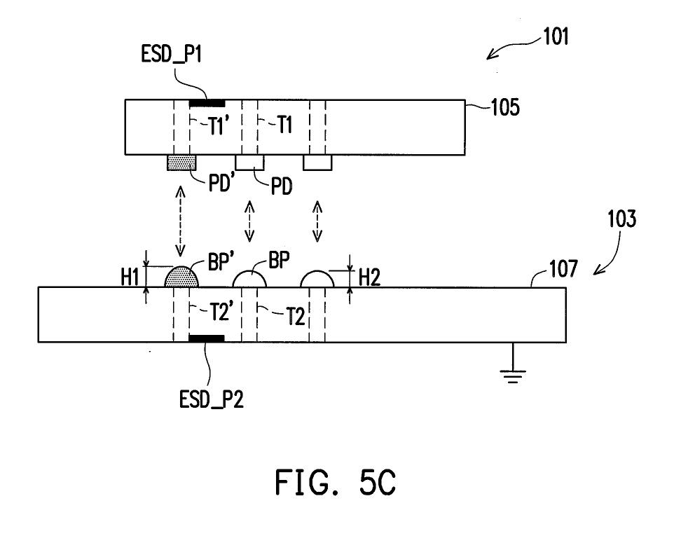

On the other hand, FIG. 5A is a schematic diagram in which the structure of the bump BP′ on the path Path-1 is altered according to an embodiment. Please refer to FIG. 5A. Compared with FIG. 1, by altering a routing length of a bottom metal of the second active layer 103 electrically connected to the bumps BP according to the present embodiment, the routing length through which a signal is transmitted to the second specific TSV T2′ is shorter than a routing length through which the signal is transmitted to the other TSVs T2. Therefore, the equivalent electrical resistance R_{BP′} of the bump BP′ is less than the equivalent electrical resistance R_{BP} of the other bumps BP.

In addition, FIG. 5B is a schematic diagram in which the structure of the bump BP′ on the path Path-1 is altered according to another embodiment. Please refer to FIG. 5B. Compared with FIG. 1, the bump BP′ corresponding to the second specific TSV T2′ according to the present embodiment has at least two sub-bumps BP11 and BP12 which are the same as the bumps BP corresponding to the other TSVs T2 and are connected in parallel. Therefore, the equivalent electrical resistance R_{BP′} of the bump BP′ is less than the equivalent electrical resistance R_{BP} of the other bumps BP.

Furthermore, FIG. 5C is a schematic diagram in which the structure of the bump BP′ on the path Path-1 is altered according to still another embodiment. Please refer to FIG. 5C. Compared with FIG. 1, a height H1 of the bump BP′ according to the present embodiment is greater than a height H2 of the other bumps BP. Therefore, the equivalent electrical resistance R_{BP′} of the bump BP′ is less than the equivalent electrical resistance R_{BP} of the other bumps BP. Moreover, according to other embodiments, by altering the electrical conductivity of the bump BP′, the electrical conductivity of the bump BP′ is greater than the electrical conductivity of the other bumps BP. Therefore, the equivalent electrical resistance R_{BP′} of the bump BP′ is less than the equivalent electrical resistance R_{BP} of the other bumps BP.

Accordingly, by altering the structure of the TSV T1′ and/or the bump BP′ on the path Path-1, the equivalent electrical resistance R_{T1′} of the TSV T1′ and/or R_{BP′} of the bump BP is less than the equivalent electrical resistance R_{T1} of the other TSVs T1 and/or R_{BP} of the other bumps BP. Hence the difference value between the equivalent electrical resistance R_{Path-1} and the equivalent electrical resistance R_{Path-2} through the paths Path-1 and Path-2 to ground is further increased, as represented by the following equation 4:

R_{Path-2}−R_{Path-1}=R_{GATE}+R_{channel}+(R_{T1}−R_{T1′})+(R_{T2}−R_{T2′})+(R_{BP}−R_{BP′}) 4

The path Path-1 is hence a path which has a smaller equivalent electrical resistance relative to the path Path-2, so that the electrical charges Q (which are static electricity) accumulated on the substrate 105 (P-sub) (which is the top layer wafer (or die)) are even more favorable for the path Path-1 over the path Path-2 to be released to the grounded substrate 107 (P-sub) (which is the bottom layer wafer (or die)).

It should be noted that although the above embodiment is described as having the corresponding ESD protection cells ESD_P1 and ESD_P2 in the first active layer 101 and the second active layer 103, the disclosure is not limited to the above configuration. In other words, in other embodiments, a plurality of pairs of the corresponding ESD protection cells ESD_P1 and ESD_P2 may be disposed in the first active layer 101 and the second active layer 103 according to actual design requirements. These alternative embodiments are also within the scope of the disclosure.

In addition, in the embodiment depicted in FIG. 1, the first active layer 101 and the second active layer 103 are described as being stacked by a back-to-back stacking process. However, the disclosure is not limited to the above configuration. In other words, according to the present embodiment, the two active layers may be stacked by a face-to-back stacking process to form the 3D IC.

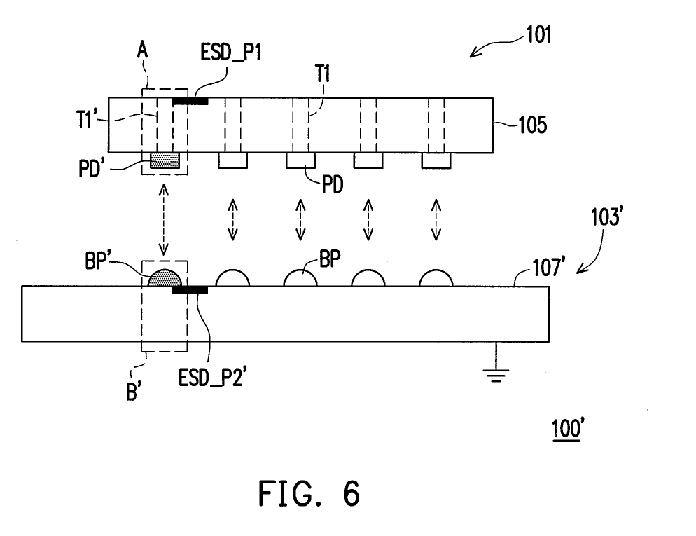

In detail, FIG. 6 is a schematic diagram of a semiconductor device 100′ according to another embodiment. Please refer to both FIGS. 1 and 6. Elements similar to those in the semiconductor device 100 are given similar reference numerals and are not repeatedly described. A difference between the semiconductor device 100′ shown in FIG. 6 and the semiconductor device 100 shown in FIG. 1 is that the first active layer 101 and the second active layer 103′ form the 3D IC by a face-to-back stacking process, whereas according to the embodiment in FIG. 1, the semiconductor device 100 is formed by a back-to-back stacking process.

According to the present embodiment, a second active layer 103′ includes a substrate 107′, a plurality of bumps BP, and at least one ESD protection cell ESD_P2′. Each of the bumps BP is located (disposed) outside the substrate 107′ and corresponds to pads PD on the first active layer 101. Additionally, the ESD protection cell ESD_P2′ includes at least one second doping area (described in detail in the following) so that the ESD protection cell ESD_P2′ is embedded in the substrate 107′ and is electrically connected to a specific bump BP′ of (among) the bumps BP by metal line. Hence the first specific TSV T1′ corresponds to the specific bump BP′.

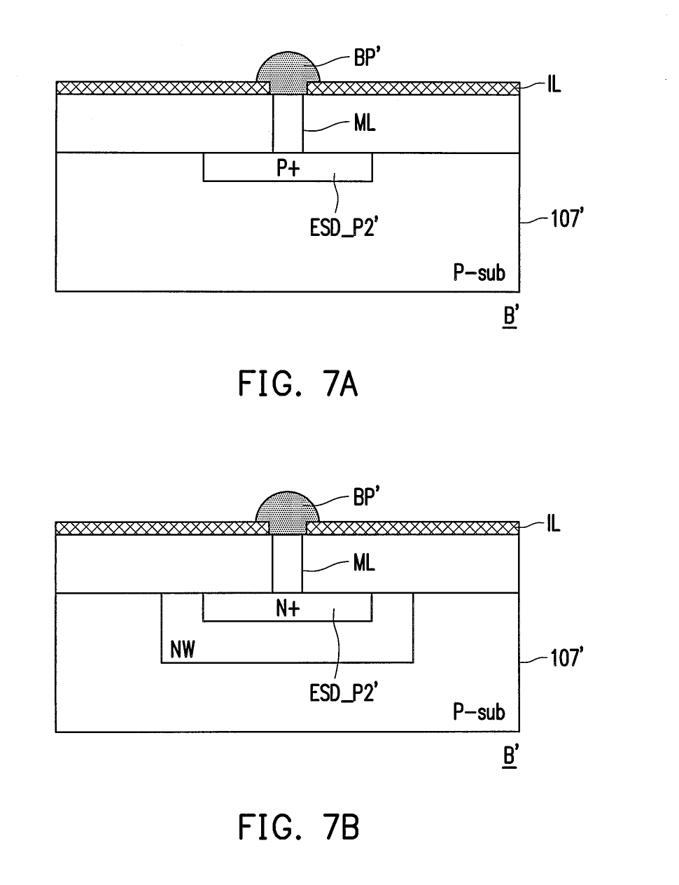

On the other hand, FIG. 7A is a schematic diagram of the ESD protection cell ESD_P2′ in a box B′ in FIG. 6 according to an embodiment. Please refer to both FIGS. 6 and 7A. According to the present embodiment, if the substrate 107′ is a P-type substrate (P-sub), the at least one second doping area of the ESD protection cell ESD_P2′ is a P+ doping area, and the specific bump BP′ and the ESD protection cell ESD_P2′ may be electrically connected to each other through a metal line ML.

Moreover, FIG. 7B is a schematic diagram of the ESD protection cell ESD_P2′ in the box B′ in FIG. 6 according to another embodiment. Please refer to both FIGS. 6 and 7B. According to the present embodiment, if the substrate 105 is the P-type substrate (P-sub), and if the second active layer 103′ further includes a well that is embedded between the substrate 107′ and the ESD protection cell ESD_P2′, the well that is embedded between the substrate 107′ and the ESD protection cell ESD_P2′ is an N-well NW, the at least one second doping area of the ESD protection cell ESD_P2′ is an N+ doping area, and the specific bump BP′ and the ESD protection cell ESD_P2′ may be electrically connected to each other through the metal line ML. According to the present embodiment, the specific bump BP′ and the substrate 107′ are insulated from each other due to the insulation layer IL.

In light of the above, in order to effectively release the electrical charges (which are static electricity) accumulated on the top layer wafer (or die) when stacking different wafers (or dies) and to dissipate heat after the stacking process, the present embodiment provides a “specific path” (which is described in detail in the following), so as to effectively release the electrical charges accumulated on the top layer wafer (or die) and to provide a heat dissipation path after the stacking process.

To be more specific, according to the above embodiments, since the ESD protection cells ESD_P1 and ESD_P2′ which are adjacent to the first TSV T1′ and connected to the specific bump BP′ have the P+ doping areas (FIGS. 2A and 7A) or the N+ doping areas (FIGS. 2B and 7B), respectively. When each of the ESD protection cells ESD_P1 and ESD_P2′ of the first specific TSV T1′ and the specific bump BP′ has a P+ doping area, the electrical charges (which are static electricity) accumulated on the substrate 105 (P-sub) (which is the top layer wafer (or die)) are guided to the grounded substrate 107′ (P-sub) (which is the bottom layer wafer (or die)) through the specific path provided by the present embodiment, thereby realizing the goal of ESD protection.

Similarly, when each of the ESD protection cells ESD_P1 and ESD_P2′ of the specific TSV T1′ and the specific bump BP′ has an N+ doping area, the electrical charges (which are static electricity) accumulated in the N-well NW in the substrate 105 (P-sub) (which is the top layer wafer (or die)) are guided to the grounded substrate 107′ (P-sub) (which is the bottom layer wafer (or die)) through the specific path provided by the present embodiment, thereby realizing the goal of ESD protection.

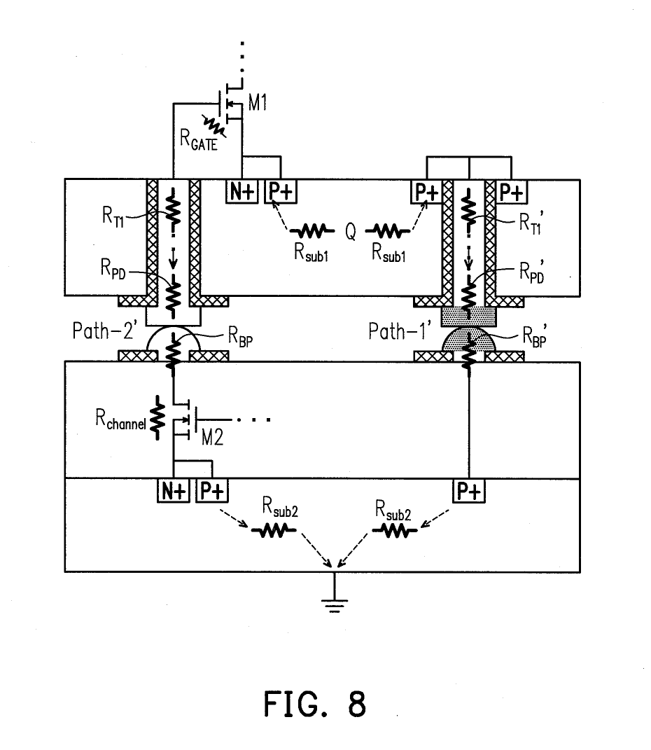

For example, FIG. 8 shows a schematic illustrative diagram related to ESD protection according to another embodiment. Please refer to FIG. 8, in which each of the ESD protection cells ESD_P1 and ESD_P2′ has a P+ doping area. An example in which each of the ESD protection cells ESD_P1 and ESD_P2′ has an N+ doping area may be deduced accordingly and is not described. A path Path-1′ shown in FIG. 8 is the “specific path” which achieves the goal of ESD protection by utilizing the ESD protection cells ESD_P1 and ESD_P2′, and a path Path-2′ is a general “conventional path” of internal circuits which are electrically connected by the TSVs T1.

According to FIG. 8, an equivalent electrical resistance R_{Path-1}′ for electrical charges Q accumulated on the substrate 105 (P-sub) (which is the top layer wafer (or die)) through the path Path-1′ to ground is represented by the following equation 5:

R_{Path-1}′=R_{sub1}+R_{T1′}+R_{PD′}+R_{BP′}+R_{sub2} 5

The items in equation 5 are described in the description for equation 1 and are hence not repeatedly described.

On the other hand, an equivalent electrical resistance R_{Path-2}′ for the electrical charges Q accumulated on the substrate 105 (P-sub) (which is the top layer wafer (or die)) through the path Path-2′ to ground is represented by the following equation 6:

R_{Path-2}′=R_{sub1}+R_{GATE}+R_{T1}+R_{PD}+R_{BP}+R_{channel}+R_{sub2} 6

The items in equation 6 are described in the description for equation 2 and are hence not repeatedly described.

It is assumed that the TSVs T1 and T1′ have the same structure, the bumps BP and BP′ have the same structure, and the pads PD and PD′ have the same structure. Under such circumstances, the equivalent electrical resistance R_{T1} and the equivalent electrical resistance R_{T1′} of the TSVs T1 and T1′ are equal (i.e. R_{T1}=R_{T1′}), the equivalent electrical resistance R_{BP} and the equivalent electrical resistance R_{BP′} of the bumps BP and BP′ are equal (i.e. R_{BP}=R_{BP′}), and the equivalent electrical resistance R_{PD} and the equivalent electrical resistance R_{PD′} of the pads PD and PD′ are equal (i.e. R_{PD}=R_{PD′}). Hence a difference value between the equivalent electrical resistance R_{Path-1}′ and the equivalent electrical resistance R_{Path-2}′ through the paths Path-1′ and Path-2′ to ground is represented by the following equation 7:

R_{Path-2}′−R_{Path-1}′=R_{GATE}+R_{channel} 7

Therefore, compared with the path Path-1′, the path Path-2′ has the equivalent electrical resistance R_{Path-2}′ which further includes the equivalent electrical resistance R_{GATE} of the gate of the NMOS transistor M1 and the equivalent electrical resistance R_{channel} of the channel of the NMOS transistor M2 when it is non-conducting. The path Path-1′ is hence a path which has a smaller equivalent electrical resistance relative to the path Path-2′, so that the electrical charges Q (which are static electricity) accumulated on the substrate 105 (P-sub) choose the path Path-1′ over the path Path-2′ to be released to the grounded substrate 107′ (P-sub) (which is the bottom layer wafer (or die)).

On the other hand, according to FIG. 8, after the top and bottom layer wafers (or dies) are stacked, heat dissipation paths of the 3D IC are provided by both of the paths Path-1′ and Path-2′. If the equivalent heat resistance of the path Path-1′ and the equivalent heat resistance of the path Path-2′ are respectively represented by R_{T-Path-1}′ and R_{T-Path-2}′, an overall heat resistance of the 3D IC is the parallel value of the equivalent heat resistance R_{T-Path-1}′ and the equivalent heat resistance R_{T-Path-2}′ of the paths Path-1′ and Path-2′ (i.e. (R_{T-Path-1}′)(R_{T-Path-2}′)/R_{T-Path-1}′+R_{T-Path-2}′), and the parallel value is less than the value of the equivalent heat resistance R_{T-Path-2}′ of the path Path-2′. Consequently, by including the specific path defined by the path Path-1′, the overall heat resistance of the 3D IC is lowered, thereby enhancing heat dissipating effects and enhancing the overall reliability of the 3D IC.

Similarly, to further ensure that the electrical charges Q (which are static electricity) accumulated on the substrate 105 (P-sub) choose the path Path-1′ over the path Path-2′ so as to be released to the grounded substrate 107′ (P-sub) (which is the bottom layer wafer (or die)), the present embodiment may also be implemented by altering the structures of the TSV T1′ and the bump BP′ on the path Path-1′. In other words, the present embodiment may be implemented by referring to the embodiments shown in FIGS. 4A to 5C and is hence not repeatedly described.

Moreover, in actual application, if the ESD protection scheme according to the above embodiments and a 2D charged device model (CDM) ESD protection scheme are combined, a CDM ESD protection scheme for a whole 3D IC is constructed.

In summary, in the ESD protection scheme according to the above embodiments, the equivalent electrical resistance of the specific path is designed to be less than that of the other paths. Hence when the first and second active layers in the semiconductor device are stacked, if suitable ESD protection units/devices (i.e. the ESD protections cells ESD_P1 and ESD_P2/ESD_P2′) are designed on these types of specific paths, the electrical charges (which are static electricity) accumulated on the top layer wafer (or die) choose these specific paths over other paths to be released to the grounded bottom layer wafer (or die), so as to achieve ESD protection effects. Furthermore, since such a specific path also functions as a heat dissipation path of the 3D IC, the overall heat resistance of the 3D IC is reduced, thereby enhancing heat dissipation effects.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A semiconductor device, comprising:
a first active layer, comprising:
a first substrate;
a plurality of first through silicon vias, wherein each of the through silicon vias passes through the first substrate; and
a first electrostatic discharge protection cell, comprising at least one first doping area, so that the first electrostatic discharge protection cell is embedded in the first substrate and is adjacent and electrically connected to a first specific through silicon via of the first through silicon vias.

2. The semiconductor device as claimed in claim 1, wherein the first substrate is a P-type substrate, and the first doping area is a P+ doping area.

3. The semiconductor device as claimed in claim 1, wherein the first active layer further comprises:
a well, embedded between the first substrate and the first electrostatic discharge protection cell.

4. The semiconductor device as claimed in claim 3, wherein the first substrate is a P-type substrate, the well is an N-well, and the first doping area is an N+ doping area.

5. The semiconductor device as claimed in claim 1, further comprising:
a second active layer, comprising:
a second substrate;
a plurality of second through silicon vias, wherein each of the second through silicon vias passes through the second substrate; and
a second electrostatic discharge protection cell, comprising at least one second doping area, so that the second electrostatic discharge protection cell is embedded in the second substrate and is adjacent and electrically connected to a second specific through silicon via of the second through silicon vias,
wherein the first specific through silicon via corresponds to the second specific through silicon via.

6. The semiconductor device as claimed in claim 5, wherein the second substrate is a P-type substrate, and the second doping area is a P+ doping area.

7. The semiconductor device as claimed in claim 5, wherein the second active layer further comprises:
a well, embedded between the second substrate and the second electrostatic discharge protection cell.

8. The semiconductor device as claimed in claim 7, wherein the second substrate is a P-type substrate, the well is an N-well, and the second doping area is an N+ doping area.

9. The semiconductor device as claimed in claim 5, wherein the first active layer further comprises:
a plurality of pads, disposed outside the first substrate and respectively corresponding and are electrically connected to the first through silicon vias.

10. The semiconductor device as claimed in claim 9, wherein the first specific through silicon via comprises at least two sub-through silicon vias that are the same as the other first through silicon vias and are connected in parallel.

11. The semiconductor device as claimed in claim 9, wherein a routing length through which a signal is transmitted to the first specific through silicon via is shorter than a routing length through which the signal is transmitted to the other first through silicon vias.

12. The semiconductor device as claimed in claim 9, wherein a width of the first specific through silicon via is greater than a width of the other first through silicon vias.

13. The semiconductor device as claimed in claim 9, wherein an electrical conductivity of the first specific through silicon via is greater than an electrical conductivity of the other first through silicon vias.

14. The semiconductor device as claimed in claim 9, wherein the second active layer further comprises:
a plurality of bumps, disposed outside the second substrate and respectively corresponding and are electrically connected to the second through silicon vias.

15. The semiconductor device as claimed in claim 14, wherein a routing length through which a signal is transmitted to the second specific through silicon via is shorter than a routing length through which the signal is transmitted to the other second through silicon vias.

16. The semiconductor device as claimed in claim 14, wherein the bump which corresponds to the second specific through silicon via comprises at least two sub-bumps that are the same as the other bumps respectively corresponding to the other second through silicon vias and connected in parallel.

17. The semiconductor device as claimed in claim 14, wherein a height of the bump which corresponds to the second specific through silicon via is greater than a height of the other bumps which respectively correspond to the other second through silicon vias.

18. The semiconductor device as claimed in claim 14, wherein an electrical conductivity of the bump which corresponds to the second specific through silicon via is greater than an electrical conductivity of the other bumps which respectively correspond to the other second through silicon vias.

19. The semiconductor device as claimed in claim 14, wherein the pads respectively correspond to the bumps.

20. The semiconductor device as claimed in claim 19, wherein the first active layer is a first wafer or a first die.

21. The semiconductor device as claimed in claim 20, wherein the second active layer is a second wafer or a second die.

22. The semiconductor device as claimed in claim 21, wherein the first active layer and the second active layer are stacked through the pads and the bumps.

23. The semiconductor device as claimed in claim 22, wherein the semiconductor device is a three dimensional integrated circuit.

24. The semiconductor device as claimed in claim 5, wherein the first active layer further comprises:
a plurality of pads, disposed outside the first substrate and respectively corresponding and electrically connected to the first through silicon vias.

25. The semiconductor device as claimed in claim 24, further comprising:
a second active layer, comprising:
a second substrate;
a plurality of bumps, disposed outside the second substrate and respectively corresponding and electrically connected to the second through silicon vias; and
a second electrostatic discharge protection cell, comprising at least one second doping area, so that the second electrostatic discharge protection cell is embedded in the second substrate and is electrically connected to a specific bump of the bumps,
wherein the second specific through silicon via corresponds to the specific bump.

26. The semiconductor device as claimed in claim 25, wherein the second substrate is a P-type substrate, and the second doping area is a P+ doping area.

27. The semiconductor device as claimed in claim 25, wherein the second active layer further comprises:
a well, embedded between the second substrate and the second electrostatic discharge protection cell.

28. The semiconductor device as claimed in claim 27, wherein the second substrate is a P-type substrate, the well is an N-well, and the second doping area is an N+ doping area.
